(19) United States
(12) Patent Application Publication
(10) Pub. No.: US 2016/0165714 A1
(43) Pub. Date: Jun. 9, 2016

(54) MULTI-LAYER PRINTED CIRCUIT BOARDS WITH LOW WARPAGE

(71) Applicant: Elite Electronic Material (Zhongshan) Co., Ltd., Zhongshan City (CN)

(72) Inventors: Ocean CHEN, Zhongshan City (CN); Li-Chih YU, Taoyuan County (TW); Xiangnan LI, Zhongshan City (CN); Xingfa CHEN, Zhongshan City (CN)

(21) Appl. No.: 14/603,067

(22) Filed: Jan. 22, 2015

(30) Foreign Application Priority Data
Dec. 4, 2014 (CN) 201410737816.2

(51) Int. Cl. H05K 1/02

(52) U.S. Cl. CPC H05K 1/02

(57) ABSTRACT

A multi-layer printed circuit board comprises: a core comprising a core insulation layer and traces formed on two sides of the core insulation layer; a plurality of insulation layers sequentially formed at two sides of the core; and a plurality of trace layers respectively formed between two insulation layers and on the outmost insulation layers; wherein the core insulation layer contains a resin material different from that of the insulation layers, such that the core insulation layer has a warpage characteristic lower than that of the insulation layers.

### CROSS-REFERENCE TO RELATED APPLICATIONS

This application claims priority to Chinese Patent Application No. 201410737816.2, filed on Dec. 4, 2014, the entirety of which is incorporated by reference herein.

### FIELD OF THE INVENTION

The present invention relates to multi-layer printed circuit boards and more particularly to multi-layer printed circuit boards with low warpage and excellent signal transmission property.

### BACKGROUND OF THE INVENTION

In order to meet the demands of compact, light-weight and conveniently portable electronic products, research and development of electronic product manufacturers are directed to and focused on miniaturization of electronic components.

Printed circuit boards are one of the essential components of many electronic products, such as smart phones, and served to provide electronic signal transmission among different electronic components. Several technical solutions have been proposed, such as high density interconnection (HDI), by printed circuit board manufacturers to reduce the size or thickness of printed circuit boards, so as to form denser trace connections within the same or even smaller size or thickness.

For example, the HDI technique employs several means to achieve high trace density, including laser blind hole drilling, small trace width and high performance thin type materials. The increase of density greatly improves the connections per unit area. In addition, the more advanced “any layer” HDI multi-layer printed circuit boards use micro-blind hole structures through plated hole filling and stacking to further achieve more sophisticated interlayer connections.

Generally, “any layer” HDI technique is different from the manufacturing processes of conventional printed circuit boards and primarily uses build-up methods to form the trace layers and insulation layers. Each build-up cycle involves lamination of prepregs and copper foils, laser drilling, hole metallization, and trace formation, including exposure, lithography, etching, etc. The aforesaid steps are carried out according to the number of layers, such as eight to fourteen layers for an ordinary mobile phone circuit board, needed to be formed to complete the multi-layer printed circuit boards.

To mount surface components, e.g. active and/or passive components, on a printed circuit board, reflow processes (reflow soldering processes) such as IR-reflow will be required to melt lead-free solder for bonding the surface components with the metal traces on the printed circuit board. However, resin material of the insulation layers in the printed circuit board is inclined to deformation during the reflow processes, deteriorating the smoothness due to laminate warpage and deformation and resulting in poor soldering such as pseudo soldering or false soldering which undesirably causes short circuit and thermal shutdown of end products.

Accordingly, there is a need to provide multi-layer printed circuit boards with low warpage and excellent signal transmission property.

### SUMMARY OF THE INVENTION

It is a primary object of the present invention to provide a multi-layer printed circuit board with low warpage, which is capable of inhibiting poor soldering resulted from warpage while maintaining desirable signal transmission property.

To achieve the aforesaid and other objects, the present invention provides a multi-layer printed circuit board comprising: a core comprising a core insulation layer and traces formed on two sides of the core insulation layer; a plurality of insulation layers sequentially formed at two sides of the core; and a plurality of trace layers respectively formed between two insulation layers and on the outmost insulation layers; wherein the core insulation layer contains a resin material different from that of the insulation layers, such that the core insulation layer has warpage characteristics lower than those of the insulation layers.

The multi-layer printed circuit board is mainly characterized in that the core insulation layer contains a resin material different from that of other insulation layers and has superior warpage performance (lower warpage) to that of other insulation layers, particularly lower warpage after being heated or cured; therefore, deformation caused by lamination of different layers can be reduced or inhibited, so as to prevent increased defective rate caused by non-compliant products. In addition, other (or external) insulation layers have a better electronic signal transmission property than that of the core insulation layer, such as lower dielectric constant or dielectric loss (dissipation factor), making them suitable for high frequency signal transmission.

As used herein, terms “resin material” and “resin composition” are synonyms for each other, both referring to a composition containing multiple components or ingredients.

In one embodiment, the warpage characteristics can be measured according to the method for measuring twist specified in IPC-TM-650 2.4.22 test methods manual. For example, the multi-layer printed circuit board has a warpage height of less than 0.6 mm and/or a warpage ratio of less than 0.4% after being subject to a 260° C. reflow process, as measured according to IPC-TM-650 2.4.22 test methods manual. Preferably, the multi-layer printed circuit board has a warpage height of less than 0.5 mm and/or a warpage ratio of less than 0.3% after being subject to a 260° C. reflow process.

In another embodiment, the insulation layers have a signal transmission property superior to the core insulation layer.

In yet another embodiment, other insulation layers have a dielectric constant less than that of the core insulation layer. For example, other insulation layers may have a dielectric constant of less than 3.6, as measured according to the JIS C2565 testing method.

In yet still another embodiment, other insulation layers have a dielectric loss less than that of the core insulation layer. For example, other insulation layers may have a dielectric loss of less than 0.010, as measured according to the JIS C2565 testing method.

In still another embodiment, the dielectric constant (e.g. less than 3.6) of other insulation layers is measured at a frequency of 2 to 10 GHz.

In still another embodiment, the dielectric loss (e.g. less than 0.010) of other insulation layers is measured at a frequency of 2 to 10 GHz.

In general, the core can be obtained by the following steps: providing a substrate, such as a glass fiber cloth, to be impregnated in a resin composition followed by baking to a semi-cured state, also known as the B-stage, the resin composition comprising but not limited to maleimide, a curing agent or a crosslinking agent, and inorganic filler, and optionally further comprising epoxy resin or cyanate ester resin; superimposing a copper foil on each of two sides of the resin composition-impregnated substrate, also known as a prepreg, and performing lamination; and forming traces from the copper foils.

In addition, the aforesaid multi-layer printed circuit board may be prepared by the following steps: providing a resin composition-impregnated substrate, such as a first prepreg, wherein the resin composition comprises without limitation maleimide, diamine crosslinking agent, such as 2,2′-bis(4-(4-aminophenoxy)phenyl)propane, and silicon dioxide inorganic filler; superimposing a copper foil on each of two sides of the substrate and performing lamination; forming traces from the copper foils to form a core having a core insulation layer; repeating the following build-up steps according to the number of layers needed: laminating a second prepreg and a copper foil onto each side of the core to make the second prepreg form an external insulation layer; performing a drilling process; performing a hole metallization process; and forming traces from the copper foils; and performing surface treatment after a number of external insulation layers needed have been formed, wherein the core insulation layer has a warpage performance superior to that of the external insulation layers, and the external insulation layers have a signal transmission property superior to that of the core insulation layer.

In one embodiment, the insulation layers of the multi-layer printed circuit board according to the present invention are formed by lamination, and the warpage characteristics, such as warpage height or warpage ratio, of the laminated multi-layer board are then measured.

### BRIEF DESCRIPTION OF THE DRAWINGS

A more complete understanding of the subject matter can be derived by referring to the detailed description and claims when considered in conjunction with the following FIGURE.

FIG. 1 illustrates a multi-layer (ten-layer) printed circuit board according to one embodiment of the present invention.

### DETAILED DESCRIPTION OF THE INVENTION

Embodiments are illustrated in the accompanying FIGURES to improve understanding of concepts as presented herein. Skilled artisans appreciate that elements in the FIGURES are illustrated for simplicity and clarity and have not necessarily been drawn to scale. For example, the dimensions of some of the elements in the FIGURES may be exaggerated relative to others to facilitate understanding of the embodiments.

Since various aspects and embodiments are merely exemplary and not limiting, after reading this specification, skilled artisans appreciate that other aspects and embodiments are possible without departing from the scope of the invention. Other features and benefits of any one or more of the embodiments will be apparent from the following detailed description and the claims.

The use of “a” or “an” is employed to describe elements and components described herein. This is done merely for convenience and to give a general sense of the scope of the invention. Accordingly, this description should be read to include one or at least one and the singular also includes the plural unless it is obvious that it is meant otherwise.

As used herein, the terms “comprises,” “comprising,” “includes,” “including,” “has,” “having” or any other variation thereof are intended to cover a non-exclusive inclusion. For example, a component, structure, article, or apparatus that comprises a list of elements is not necessarily limited to only those elements but may include other elements not expressly listed or inherent to such component, structure, article, or apparatus. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present).

One embodiment of the present invention provides a multi-layer printed circuit board, such as a multi-layer printed circuit board made using the HDI technique, mainly comprising a core comprising a core insulation layer and traces formed on two sides of the core insulation layer; a plurality of insulation layers sequentially formed at two sides of the core; and a plurality of trace layers respectively formed between two insulation layers and on the outmost insulation layers.

Unless expressly stated to the contrary, the number of layers of the multi-layer printed circuit board is not specifically limited; it may be an eight-layer, ten-layer, twelve-layer, fourteen-layer, or sixteen-layer board, wherein the layer number of the board is determined by the number of conductive layers (e.g. copper trace layers) in the multi-layer printed circuit board.

The aforesaid core may be prepared according to the following process: impregnating a substrate, such as a conventional glass fiber cloth 1078, into a first resin composition and then baking it to a semi-cured state (i.e. B-stage) to obtain a prepreg; cutting the prepreg according to a predefined size requirement; superimposing a piece of 0.5 oz HTE copper foil on each of two sides and carrying out lamination and curing for three hours under vacuum, high temperature (195° C.) and high pressure (500 psi); and optionally fabricating traces, such as using exposure, lithography and etching processes, on the copper foil to obtain the core.

In one embodiment, the first resin composition may comprise maleimide, a curing agent or a crosslinking agent, and inorganic filler, and the first resin composition may be any resin composition suitable for making an insulation layer with lower warpage, such as a composition of maleimide and diphenylamine or bismaleimide triazine (BT) resin, which may further comprise cyanate ester resin or epoxy resin. It may also be the EM-LX composition available from Elite Material Co., Ltd.

Once the core has been made, a prepreg is superimposed on each side of the core, and a 0.5 oz HTE copper foil is superimposed on each prepreg, which is then subject to a vacuum condition, high temperature (175° C.) and high pressure (360 psi) for lamination and curing for an hour to complete the first lamination, optionally followed by the drilling process, hole metallization process and trace formation process to complete the first build-up cycle to form a four-layer board.

The prepregs used in the above-mentioned build-up cycle can be obtained by, for example, impregnating a conventional glass fiber cloth 1067 in a second resin composition and then baking it to the B-stage, wherein the second resin composition is different from the first resin composition and is a low dielectric material with a Dk less than 3.5 as measured at 2 GHz frequency. For example, the second resin composition may be the EM-355(D) composition (Dk=3.33 as measured at 2 GHz frequency) available from Elite Material Co., Ltd. Accordingly, the external insulation layers, which contain low dielectric material, formed in the build-up steps may provide a better signal transmission property.

Afterwards, a second or subsequent build-up cycle can be performed according to the need to form a printed circuit board with the desired number of layers. For example, a ten-layer board can be obtained by subjecting the core to four build-up cycles. Then surface treatment and other post-processing procedures commonly used in the manufacturing process of printed circuit boards can be carried out to obtain a multi-layer printed circuit board product.

A major feature of the present invention lies in using a resin material capable of forming a product with lower warpage during the process to make the core to achieve a better (i.e. lower) warpage characteristics, such that the circuit board thus made can be prevented from serious warpage during or after the reflow process (260° C. to 288° C.). In addition, materials with better signal transmission property, such as low dielectric constant (Dk<3.5, as measured at 2 GHz frequency, but not limited thereto), are used to build up the external layers, such that the insulation layers formed in the build-up steps can attain high transmission speed.

In terms of signal transmission of multi-layer printed circuit boards, signals at low frequency (<1 GHz) are primarily transmitted by the trace layers (e.g. copper trace layers), and signal transmission at high frequency (>1 GHz, such as 2 GHz) is associated to the property of insulation layers (also known as dielectric layers). For example, the relationship between the transmission rate V and Dk of an insulation layer is as follows: V=k*c/\sqrt{Dk}, wherein V represents the signal transmission speed, c represents the speed of light, k is a constant, and Dk represents the dielectric constant. Therefore, the lower the dielectric constant of an insulation layer, the faster the transmission speed V.

A primary advantage of the present invention is using a low warpage material as the core layer to ensure low warpage of the circuit board in subsequent processes and using a high signal transmission property material as other insulation layers (a.k.a. dielectric layers) to effectively increase the signal transmission speed, thereby overcoming at the same time the following three problems associated to a multi-layer printed circuit board architecture: (A) serious warpage and poor signal transmission speed of multi-layer boards using ordinary FR-4 material; (B) serious warpage of multi-layer boards using ordinary low Dk material; and (C) low signal transmission speed of multi-layer boards using low warpage material, as materials with low warpage characteristics usually have higher dielectric constant, and other problems associated to high material costs, demand for higher lamination temperature and the accompanying higher lamination costs, poor thermal resistance of copper foil after brown oxidation, and poor processability for routing and trimming.

### Embodiments

The core of Example 1 is made by the following process: preparing a first prepreg (EM-LX, available from Elite Material Co., Ltd., containing 1078 glass fiber cloth), superimposing a 0.5 oz HTE copper foil on each of two sides of the first prepreg and carrying out lamination and curing for three hours under vacuum, high temperature (195° C.) and high pressure (500 psi) to obtain a copper-clad laminate, and fabricating traces, such as using conventional exposure, lithography and etching processes, on the copper foil to obtain the core, which has a thickness of about 2.4 mils.

The build-up process for Example 1 is performed as follows: after the core has been obtained, second prepregs (EM-355(D), using 1067 glass fiber cloth) are prepared; a second prepreg is superimposed on each of the two sides of the core, and a 0.5 oz HTE copper foil is further superimposed on the other side of the prepreg opposite to the core, followed by lamination and curing for an hour under vacuum, high temperature (175° C.) and high pressure (360 psi) to complete the first lamination. Then the drilling process is performed; alignment holes are formed by drilling, followed by the hole metallization process and trace formation process to complete the first build-up cycle to form a four-layer board.

The above-mentioned build-up steps are repeated to form a six-layer board (second build-up cycle, second lamination), and then an eight-layer board (third build-up cycle, third lamination) until a ten-layer board (fourth build-up cycle, fourth lamination) has been formed.

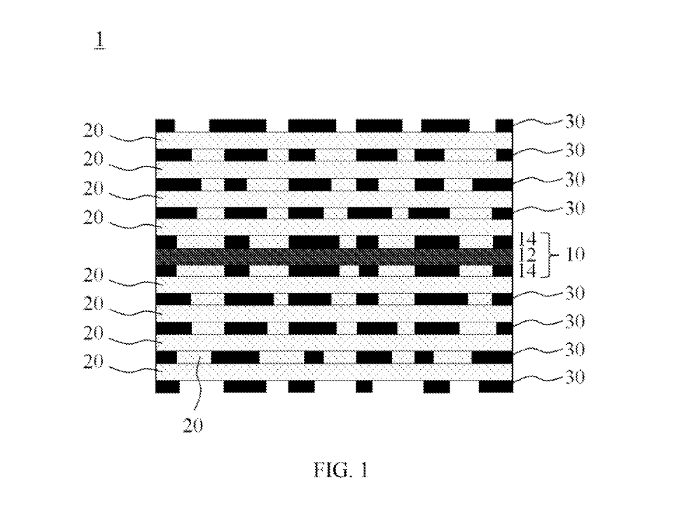

The ten-layer boards thus made for the Example and Comparative Examples, each having 24 samples, are individually cut to a length of 150 mm, a width of 78 mm and a diagonal length of 169 mm to obtain a multi-layer (ten-layer) printed circuit board 1 as shown in FIG. 1, which mainly comprises a core 10 having a core insulation layer 12 and traces 14 formed on two sides of the core insulation layer 12; a plurality of insulation layers 20 formed by the build-up process and sequentially formed at two sides of the core 10; and a plurality of traces 30 respectively formed between two adjacent insulation layers 20 and on the outmost insulation layers 20. Said ten-layer printed circuit board 1 can be obtained by any methods already disclosed in the art, and the materials for the core and insulation layers can be obtained from products already sold by Elite Material Co., Ltd., wherein the cores used in the Example and Comparative Examples contain glass fiber clothes as the substrates, and each core insulation layer is characterized by having the following material properties listed in Table 1 below.

TABLE 1

| | Ex. 1 | Comp. Ex. 1 | Comp. Ex. 2 |
|---|---|---|---|
| Material of core | Low warpage | Low dielectric | General FR-4.1 |
| | material | material | material |
| | EM-LX | EM-355(D) | EM-285 |
| Material of insulation | Low dielectric | Low dielectric | Low dielectric |
| layers formed by first | material | material | material |
| to fourth build-up | EM-355(D) | EM-355(D) | EM-355(D) |
| cycles | | | |

The core and (build-up) insulation layers in the Example and Comparative Examples use glass fiber clothes as the substrates, and three different resin materials have the following material properties listed in Table 2.

TABLE 2

| | | | General |
|---|---|---|---|
| | Low warpage | Low dielectric | FR-4.1 |
| | material | material | material |
| | EM-LX | EM-355(D) | EM-285 |
| Warpage height (mm) of | 4.5 | 8.9 | 17.3 |
| core with copper foil on | | | |
| single side subject to | | | |
| one reflow process (260° C.) | | | |
| Warpage ratio (%) of | 1.3% | 2.6% | 5.1% |
| core with copper foil on | | | |
| single side subject to | | | |
| one reflow process (260° C.) | | | |
| Dielectric constant Dk, | 3.45 | 3.33 | 3.80 |
| measured from 75% | | | |
| resin content and 2 GHz | | | |
| frequency | | | |

Table 2 above compares the material properties of low warpage material EM-LX, low dielectric material EM-355(D) and general FR-4.1 material EM-285, wherein the warpage height and warpage ratio are measured according to the method described below: preparing a first prepreg (using 1078 glass fiber cloth), superimposing a piece of 0.5 oz HTE copper foil on each of two sides of the first prepreg, carrying out lamination and curing for three hours under vacuum, high temperature (195° C.) and high pressure (500 psi) to obtain a copper-clad laminate with copper on both sides, then removing by etching the copper foil on one side of the copper-clad laminate and preserving the copper foil on the other side to obtain a core with copper foil on single side, and finally subjecting the core with copper foil on single side obtained from each of the three materials to warpage height and warpage ratio measurements according to the methods recited in the IPC-TM-650 2.4.22 test methods manual.

In Table 2 above, because the warpage height and warpage ratio of copper-free cores are too small for effective measurement and observation, cores with copper foil on single side with more apparent warpage height and warpage ratio are used for the purpose of comparison. In addition, the dielectric constant Dk is measured by a cavity resonator (according to the JIS C2565 testing procedure) from a copper-free laminate made by two prepregs obtained by impregnating 1067 glass fiber clothes with a resin composition and baking to the semi-cured state.

In addition, for the Example and Comparative Examples, warpage characteristics of each sample circuit board treated by one 260° C. reflow process are measured according to the description of twist measurement recited in the IPC-TM-650 2.4.22 test methods manual, in which the ten-layer board is cut to a size of 150 mm in length, 78 mm in width and 169 mm in diagonal length of the maximum plane, and then placed on a marble platform; a height gauge is used to measure the vertical distance from one corner of the circuit board with maximum warpage to the plane defined by the other three corners as the warpage height. The warpage ratio is defined as: Warpage Ratio=(Warpage Height/Diagonal Length)*100%. 24 samples are used for the measurements of each of Example E1 and Comparative Examples C1 and C2.

The warpage height and warpage ratio of the ten-layer boards for each Example and Comparative Examples are listed in Table 3 and Table 4 below.

TABLE 3

| | Maximum | Average | | Average |
|---|---|---|---|---|
| | warpage | warpage | Warpage ratio | warpage |
| Example | height (mm) | height (mm) | (%) | ratio (%) |
| Ex. 1 | 0.17 | 0.41 | 0.10 | 0.24 |
| | 0.54 | | 0.32 | |
| | 0.60 | | 0.35 | |
| | 0.40 | | 0.24 | |
| | 0.56 | | 0.33 | |
| | 0.44 | | 0.26 | |
| | 0.34 | | 0.20 | |
| | 0.35 | | 0.21 | |
| | 0.58 | | 0.34 | |
| | 0.54 | | 0.32 | |
| | 0.53 | | 0.31 | |
| | 0.43 | | 0.25 | |
| | 0.43 | | 0.25 | |
| | 0.39 | | 0.23 | |
| | 0.48 | | 0.28 | |
| | 0.53 | | 0.31 | |
| | 0.30 | | 0.18 | |
| | 0.29 | | 0.17 | |
| | 0.56 | | 0.33 | |
| | 0.19 | | 0.11 | |
| | 0.16 | | 0.09 | |
| | 0.41 | | 0.24 | |
| | 0.37 | | 0.22 | |
| | 0.26 | | 0.15 | |
| Comp. Ex. 1 | 0.86 | 0.68 | 0.51 | 0.41 |
| | 0.59 | | 0.33 | |
| | 0.95 | | 0.50 | |
| | 0.76 | | 0.39 | |
| | 0.51 | | 0.30 | |
| | 0.93 | | 0.55 | |
| | 0.62 | | 0.37 | |
| | 0.70 | | 0.41 | |
| | 0.41 | | 0.18 | |
| | 0.77 | | 0.46 | |
| | 0.49 | | 0.29 | |
| | 0.68 | | 0.40 | |
| | 0.74 | | 0.44 | |
| | 0.82 | | 0.49 | |
| | 0.47 | | 0.28 | |
| | 0.52 | | 0.31 | |
| | 0.39 | | 0.18 | |
| | 0.76 | | 0.45 | |
| | 0.96 | | 0.57 | |
| | 0.74 | | 0.44 | |
| | 0.84 | | 0.50 | |
| | 0.60 | | 0.35 | |
| | 0.74 | | 0.20 | |
| | 0.65 | | 0.31 | |
| Comp. Ex. 2 | 0.50 | 0.78 | 0.30 | 0.46 |
| | 1.11 | | 0.66 | |
| | 0.78 | | 0.46 | |
| | 0.89 | | 0.53 | |
| | 0.84 | | 0.50 | |
| | 0.99 | | 0.59 | |
| | 0.76 | | 0.45 | |
| | 0.69 | | 0.41 | |
| | 0.43 | | 0.25 | |
| | 0.86 | | 0.51 | |
| | 1.07 | | 0.63 | |
| | 0.83 | | 0.49 | |
| | 0.86 | | 0.51 | |
| | 0.52 | | 0.31 | |
| | 0.72 | | 0.43 | |
| | 0.66 | | 0.39 | |
| | 0.95 | | 0.56 | |
| | 0.58 | | 0.34 | |
| | 0.49 | | 0.29 | |
| | 0.72 | | 0.43 | |
| | 0.93 | | 0.55 | |
| | 0.66 | | 0.39 | |
| | 1.04 | | 0.62 | |
| | 0.77 | | 0.46 | |

TABLE 4

| | Average | | | |
|---|---|---|---|---|
| | warpage | Maximum | Minimum | Difference in |
| | ratio | warpage ratio | warpage ratio | warpage ratio |
| | (%) | (%) | (%) | (%) |
| Ex. 1 | 0.24 | 0.35 | 0.09 | 0.26 |
| Comp. Ex. 1 | 0.41 | 0.57 | 0.23 | 0.34 |
| Comp. Ex. 2 | 0.46 | 0.66 | 0.25 | 0.40 |

From the result shown above, the following observations can be made: the ten-layer circuit board of Example 1, in which the core is made from low warpage material and the other insulation layers are made from low dielectric material, demonstrates lower average warpage height and lower average warpage ratio, and the difference between the maximum warpage ratio and minimum warpage ratio is relatively low, showing the example of this invention achieves better warpage performance. In contrast, the cores of Comparative Examples 1 and 2 contain low dielectric material and general FR-4.1 material respectively, and greater average warpage height and greater average warpage ratio are observed.

The above detailed description is merely illustrative in nature and is not intended to limit the embodiments of the subject matter or the application and uses of such embodiments. As used herein, the term “exemplary” means “serving as an example, instance or illustration.” Any implementation described herein as exemplary is not necessarily to be construed as preferred or advantageous over other implementations.

Moreover, while at least one exemplary embodiment has been presented in the foregoing detailed description, it should be appreciated that a vast number of variations exist. It should also be appreciated that the exemplary one or more embodiments described herein are not intended to limit the scope, applicability or configuration of the claimed subject matter in any way. Rather, the foregoing detailed description will provide those skilled in the art with a convenient guide for implementing the described one or more embodiments. Also, various changes can be made in the function and arrangement of elements without departing from the scope defined by the claims, which include known equivalents and foreseeable equivalents at the time of filing this patent application.

What is claimed is:

1. A multi-layer printed circuit board comprising:
a core comprising a core insulation layer and traces formed on two sides of the core insulation layer;
a plurality of insulation layers sequentially formed at two sides of the core; and
a plurality of trace layers respectively formed between two insulation layers and on the outmost insulation layers;
wherein the core insulation layer contains a resin material different from that of the insulation layers, such that the core insulation layer has a warpage characteristic lower than that of the insulation layers.

2. The multi-layer printed circuit board of claim 1, wherein the warpage characteristic is warpage height.

3. The multi-layer printed circuit board of claim 1, wherein the warpage characteristic is warpage ratio.

4. The multi-layer printed circuit board of claim 2, wherein the multi-layer printed circuit board has a warpage height of less than 0.6 mm after being subject to a 260° C. reflow process.

5. The multi-layer printed circuit board of claim 3, wherein the multi-layer printed circuit board has a warpage ratio of less than 0.4% after being subject to a 260° C. reflow process.

6. The multi-layer printed circuit board of claim 2, wherein the multi-layer printed circuit board has a warpage height of less than 0.5 mm after being subject to a 260° C. reflow process.

7. The multi-layer printed circuit board of claim 3, wherein the multi-layer printed circuit board has a warpage ratio of less than 0.3% after being subject to a 260° C. reflow process.

8. The multi-layer printed circuit board of claim 1, wherein the insulation layers have a dielectric constant less than that of the core insulation layer.

9. The multi-layer printed circuit board of claim 1, wherein the insulation layers have a dielectric loss less than that of the core insulation layer.
